(19) United States
(12) Patent Application Publication
(10) Pub. No.: US 2025/0038468 A1
(43) Pub. Date: Jan. 30, 2025

(54) Package Comprising At Least Two Contacts For Microtechnology, Method For Handling A Package, And Tool For Implementing The Method

(71) Applicant: Pac Tech - Packaging Technologies GmbH, Nauen (DE)

(72) Inventors: Matthias Fettke, Berlin (DE); Andrej Kolbasow, Paulinenaue (DE); Thorsten Krause, Hoppegarten (DE)

(21) Appl. No.: 18/770,958

(22) Filed: Jul. 12, 2024

(30) Foreign Application Priority Data
Jul. 28, 2023 (DE) 10 2023 120 137.9

(51) Int. Cl. H01R 43/02; H01R 4/02

(52) U.S. Cl. CPC H01R 43/0263; H01R 4/02

(57) ABSTRACT

A package comprises at least two contacts for microtechnology, the contacts each having a contact surface, the contacts being connected to at least one support structure and the contacts being spaced apart from each other and disposed in such a manner that the contact surfaces are disposed in one plane and are oriented in the same direction. The support structure is made of a connective material being separable and/or destroyable by a laser. Furthermore, a method for handling such a package and a tool for implementing such a method are provided.

### CROSS-REFERENCE TO RELATED APPLICATION

This application claims priority to German Patent Application No. 10 2023 120 137.9 filed Jul. 28, 2023, the disclosure of which is incorporated herein by reference in its entirety for all purposes.

### TECHNICAL FIELD

The disclosure relates to a package comprising at least two contacts for microtechnology, to a method for handling the package comprising at least two contacts for microtechnology, and to a tool for implementing the method.

### BACKGROUND

Due to the small structures in microtechnology, the handling and production of electronic components is particularly cumbersome and must be carried out with high precision. In particular the placement of contacts must be precise, as otherwise parts of the electronic component could be short-circuited by the wrong placement of the contact or not be sufficiently contacted and would not function as expected. A correction is impossible in most cases, which makes the electronic component unusable. If the placement is not precise, a large number of reject parts is the result. The exact placement, however, is time-intensive.

### SUMMARY

Consequently, high demand exists for an accelerated, though simultaneously precise method for providing and placing contacts, whereby time and labor efforts can be saved, without having to accept lesser quality of the electronic components.

The object of the invention is therefore to provide contacts in a manner which allows a simultaneous and still precise placement of the contacts, thus yielding savings in time. In doing so, this method can still be carried out with the usual high precision.

This object is attained in a surprisingly simple and effective manner by a package comprising at least two contacts as disclosed herein and a method for placing these contacts as disclosed herein.

According to the invention, a package comprising at least two contacts for microtechnology is proposed, the contacts each having a contact surface, and the contacts being connected to at least one support structure and the contacts being spaced apart from each other and disposed in such a manner that the contact surfaces are disposed in one plane and are oriented in the same direction.

The package is characterized in that the support structure is made of a connective material being separable and/or destroyable by means of a laser. The invention is based on the basic idea that in electronic components in microtechnology the contacts are generally disposed at predefined locations at a predefined distance to each other on the electronic component. The position of these predefined locations is yielded beforehand from the design of the electronic component. In the scope of the invention, it has been recognized that the predefined locations have a set distance to each other in order to allow a compatibility of as many electronic components as possible. The predefined locations are disposed in one plane and are oriented in the same direction. This means that if at least two contacts are disposed on the electronic component at a set distance before mounting, the set distance corresponding to the distance of the predefined locations on the electronic component, the precise orientation of a contact is sufficient in order to also precisely and correctly orient the at least one other contact. This consequently saves time because several contacts can be precisely oriented simultaneously.

In this context, the precise distance as intended by the invention is ensured by the support structure which stabilizes the contacts at set distances to each other and enables moving the contacts together.

After mounting, however, it is necessary to remove the support structure, as otherwise an unintended short circuit which would impair the function of the electronic component would arise between the at least two contacts. As the structures in microtechnology are very small, the separation and/or destruction of the support structure must be very precise. A laser beam is characterized by its coherent light and its high intensity, thus making it possible to yield an energy input in a selective and targeted manner with high precision. Due to the small structures in microtechnology, a selective and targeted separation and destruction of the support structure, said support structure being separable and/or destructible by means of a laser, are enabled by means of the laser without causing damage to other areas of the package, in particular the contacts, and/or to the electronic component. A contact in microelectronics serves to establish an electrically conductive connection, for example to another electronic component or to an electrical conductor. For this purpose, the contacts must be fixed on the electronic component at predefined locations, which are typically disposed at predefined distances to each other. The predefined locations are connected to an internal circuit of the electronic component, which leads to its functionality. Aside from or instead of the electrical connection, several contacts can establish a mechanical connection to a different electronic component. As a rule, the contacts are designed in such a manner that simply attaching a contact on a different electronic component is possible. Other designs of the contacts are also conceivable.

The package comprises at least two contacts, which are to be placed and mounted simultaneously. Preferably, the package comprises at least 2, 3, 4, 5, 6, 7, 8, 9, 10, 11, 12, 13, 14, 15, 16, 17, 18, 19, 20, 25, 30, 35, 40, 45, 50, 55, 60, 65, 70, 75, 80, 85, 90, 95 or 100 contacts. The contacts have a contact surface, which serves for being electrically and/or mechanically connected to the electronic component at the predefined locations. For this reason, it is necessary for the at least two contacts having the contact surface to be disposed in such a manner that the contact surfaces are in one plane, are oriented in the same direction and are disposed at the predefined distance. In this manner, the contacts can be attached simultaneously at two or more adjacent predefined locations of the electronic component. To ensure this orientation and the distance of the contacts to each other during the entire handling, the package has a support structure. This means the support structure has the task of fixing the contacts to each other such that the contact surfaces remain disposed in one plane and oriented in the same direction as well as of ensuring the distance in doing so. The person skilled in the art is familiar with suitable materials which have both the required separability and/or destructibility and the required stability. Suitable materials are in particular metals and metal alloys. A suitable method for separation and/or destruction by means of a laser is described elsewhere.

Preferably, the connective material has a thermal conductivity of at least 10 W/mK. In the scope of the invention, it has been recognized that several methods for applying contacts on the electronic component are used in microtechnology, these methods requiring heat or being heat-induced for establishing the connection between the electronic component and the contact during mounting. The application of heat on all contacts is cumbersome. In the scope of the invention, it has been recognized that the support structure is generally suited for conducting heat from one contact to another. For this purpose, the support structure is made of a material which has a thermal conductivity of at least 10 W/mK. The heat can then be conducted from one contact to all other contacts of the package, meaning all contacts can be sufficiently heated when one of the contacts is heated. This means it is possible to simultaneously attach all contacts of the package on the electronic component in addition to simultaneously placing them. In doing so, the support structure takes over the additional task of conducting the heat required for the connection process of the contacts, when said contacts are mounted on the electronic component, to all contacts of the package. To enable this, the support structure is made of a connective material having a thermal conductivity of at least 10 W/mK. Due to the small structures in microtechnology, this is a sufficiently high thermal conductivity, with a higher thermal conductivity being preferred.

The term “package” refers to a sorted compound of at least two contacts fixed with respect to each other.

The term “contact” refers to a conductive component which serves for the electrical and/or mechanical connection of an electronic component to another electronic component or to an electrical conductor.

The term “support structure” refers to a structure which suitably fixes at least two contacts with respect to each other.

The term “connective material” refers to the material of which the support structure is made.

The package according to the invention makes it possible to install several contacts in an electronic component of microtechnology at the same time, as the contacts are placed simultaneously and can be connected simultaneously to the electronic component. This saves significantly on time and effort.

Advantageous embodiments of the invention, which can be realized individually or in combination with each other, are detailed in the dependent claims.

It is conceivable for the contacts to be made of a contact material, the connective material having a lower combustion and/or melting point than the contact material. As described above, it is necessary to separate and/or to destroy the support structure after the contacts have been mounted on the electronic component in order to eliminate the short circuit between two contacts caused by the support structure. This is made possible for example by burning and/or melting the support structure. In order to not impair the functionality of the contacts in this process, it is advantageous if the connective material of the support structure has a lower combustion and/or melting point than the contact material.

Alternatively, it is conceivable for the connective material and the contact material to be identical and to therefore have identical properties in order to thus enable a quick and simple production of the package according to the invention.

In a further embodiment, it is conceivable for the contacts to be flat and disposed parallel to one another. The flat design allows placing the contacts at the preferred distance to each other. As a rule, the predefined locations, which set the distance of the contacts, are adjacent to each other and the contacts are intended to be disposed at said locations parallel to each other at a later stage. In this case, it is advantageous if the contacts are flat and disposed parallel to each other.

The term “flat” refers to an embodiment in which the extension of a contact in one spatial direction, the height, is significantly smaller than in the other two spatial directions. Particularly preferably, the contacts are designed as extrusion bodies, in particular as prisms, the extrusion taking place in the direction of the height. The term “parallel” refers to the orientation of the flat contacts, such that the lateral surfaces, which limit the height, are oriented parallel to each other.

Moreover, it is conceivable for the contacts to be designed to be identical. An identical design of the contacts allows a simple and predictable handling. A different design of the contacts allows a targeted adaptation of the contacts to the electronic component in which they are to be later installed. In doing so, it is conceivable that, in a package, at least a first portion of contacts, i.e., a first number of contacts, is contained in a first embodiment and at least a second portion of contacts, i.e., a second number of contacts, is contained in a second embodiment. In this context, the first portion of the contacts can comprise identical contacts, for example, and a second portion of the contacts can also comprise identical contacts, albeit being different compared to the first design.

It is further conceivable for the contacts to be oriented in the same direction and/or different directions. The contacts are disposed in such a manner that the contact surfaces are disposed in one plane and are oriented in the same direction. However, this allows rotating the contacts with respect to each other about an axis perpendicular to this plane and/or a parallel displacement of the contacts in this plane. If the contacts are oriented in the same direction, they can be transferred into each other via a simple displacement in the plane, no rotation of the individual contacts being necessary. If the contacts are oriented in different directions, a rotation in the plane is required to transfer the contacts into each other. It is particularly preferred for the contacts to be oriented in different directions. Most preferably, the contacts are oriented so as to be rotated by 180° with respect to each other. In this context, in packages having three or more contacts, it is also conceivable for a first portion of the contacts to be oriented in the same direction and a second portion of the contacts to be oriented in the same direction, and the first portion to be oriented in a different direction with regard to the second portion.

In yet another further embodiment of the invention, it is conceivable for at least one contact to comprise at least one recess. Preferably, at least 2, 3, 4, 5, 6, 7, 8, 9, 10, 11, 12, 13, 14, 15, 16, 17, 18, 19, 20, 25, 30, 35, 40, 45, 50, 55, 60, 65, 70, 75, 80, 85, 90, 95 or 100 contacts, in particular all contacts, of the package comprise at least one recess. Even more preferably, at least one contact comprises 2, 3, 4, 5, 6, 7, 8, 9 or 10 identical or different recesses. The shape of the recess is generally of no consequence, though particularly preferably the recess is rectangular. In the recess, a part of the support structure can be received so the contacts can be connected to the support structure in a simple, yet reliable manner and can be fixed by this.

Moreover, it is conceivable that the support structure comprises at least one bar. A bar is an oblong component which is preferably round or rectangular. A bar is easy to produce, yet can be effectively used as a support structure. In this context, it is conceivable for the bar to be disposed at least partially in at least one recess, as described elsewhere, of one, two, more or all contacts. Further preferably, it is conceivable for the bar to be disposed laterally on the contacts.

It is further conceivable for the support structure to comprise at least one block, the block being disposed between two contacts. A block is a polyhedron, preferably a limited polyhedron and/or a polyhedron made up of cuboids. Particularly preferably, the block is a cuboid. In this context, a first contact is disposed on at least one first lateral surface of the block and a second contact is disposed on at least one second lateral surface of the block, the second lateral surface preferably being opposite the first lateral surface. A block is preferably applied on a contact, in particular a lateral surface of the contact.

In a further embodiment, it is conceivable for the package to comprise at least three contacts and for the support structure to be designed in multiple pieces having a first part, the first part of the support structure being connected to two contacts. This means that the first part of the support structure is connected to merely two of the three contacts. In this context, it is conceivable for the first part to be a block. Preferably, the first part is disposed between two adjacent contacts. Alternatively, however, it is conceivable for the first part to be connected to two non-adjacent contacts. This is possible in particular when at least two of the three contacts are designed to be different and/or are oriented in different directions.

It is conceivable for the support structure to be connected to the contacts in a substance-to-substance bond and/or to be designed monolithical with the contacts. A substance-to-substance bond and/or a monolithic design guarantees a secure hold between the support structure and the contacts, the fixation of the contacts with respect to each other and the heat transmission from the support structure to the contacts being optimally ensured.

The term “monolithic” refers to an object which is designed contiguously consisting of one piece and having no grooves and which cannot be separated without being destroyed.

In another further embodiment of the invention, it is conceivable for the package to be layered. In this context, it is preferred for a mask to first be applied on a suitable structure and/or surface by means of photo lithography for shaping the contact and for a first contact to be subsequently produced by means of ion plating. The photoresist forming the mask is removed together with the excess coating, and subsequently another mask is produced by means of photo lithography and the support structure is made by means of ion plating. The photoresist of the support-structure mask is removed together with the excess coating and another mask is produced for another contact. The steps are repeated until the desired number of contacts in the package has been yielded. The layered design means the package can be produced quickly, easily and precisely.

In yet another further embodiment of the invention, it is conceivable for the package to have a length, a width and/or a height of at least 2500 μm. As described above, the package is intended for use in microtechnology. These dimensions correspond to those used in microtechnology.

It is presumed that the definitions and/or descriptions of the above terms apply to all aspects described in the following description, provided no statements have been made to the contrary.

According to the invention, a method for handling a package as described elsewhere is proposed, the method comprising the following steps:
a. grasping the package.
b. heating at least one of the contacts and bonding the contact surfaces of all contacts of the package.
c. separating and/or destroying the support structure by means of a laser.

In the scope of the invention, it has been recognized that simultaneously processing the contacts, in particular simultaneously bonding the contacts of the package, saves on time. This is achieved by handling several contacts at the same time. The advantage can be achieved in particular by the predefined locations of the electronic components, on which the contacts are attached, generally having a predefined distance and a predefined orientation to each other. For this reason, it is possible to dispose the contacts at this distance in a manner fixed by the support structure as early as during their production. In this manner, a simultaneous grasping of several contacts is possible which can then be precisely disposed simultaneously at the different predefined locations by the first contact being precisely disposed. The support structure according to the invention allows heating all contacts simultaneously by heating only one contact. However, the support structure causes a short circuit impairing the functionality of the electronic component. For this reason, the support structure must be destroyed as a last step.

A laser beam is characterized by its coherent light and its high intensity, meaning it is possible to yield an energy input selectively and in a targeted manner at high precision. Due to the small structures in microtechnology, the targeted separation and/or destruction of the support structure is enabled by means of the laser without damaging other areas of the package, in particular the contacts, and/or the electronic component.

First, the package is grasped by means of a suitable tool. After the grasping, it is possible to transport the package by means of the tool, in particular to the electronic component into which it is to be installed. In the next step, which can take place before, during and/or after the transport of the package to the predefined locations, the package is heated in preparation for the bonding. In doing so, the contact surfaces of the contacts come to rest on the predefined locations and/or on the materials being applied there and enabling the bonding. Subsequently, the support structure is destroyed and/or separated.

Preferably, the heating in step b. is also carried out by means of a laser. By means of the laser, the package can be heated selectively and in a targeted manner at at least one contact, without damaging other areas of the package, in particular the contacts, and/or the electronic component. In a preferred embodiment, the laser beam is directed on at least one of the contacts during heating.

The term “bonding” refers to the forming of an electrical and/or mechanical permanent connection between a contact and a predefined location of an electronic component.

The term “separating” refers to the process during which the support structure is divided and/or split into two or more parts.

The term “destroying” refers to the process of damaging the support structure so that it loses its functionality. The functionality of the support structure in this context is fixing the contacts with respect to each other.

In another further embodiment of the invention, it is conceivable that the separation and/or destruction of the support structure in step c. is implemented by ablation by means of a laser. Ablation is a simple, quick and precise method for separating and/or destroying the support structure.

In connection with lasers, the term “ablation” refers to a process during which the support structure is ablated via the use of a laser, the energy of the laser being directed, in particular pulsed, in a targeted manner on the material whereby the material evaporates or is ablated in the form of particles. In doing so, the connective material of the support structure is heated at the surface for a short period of time to such high temperatures that the electrons forming the chemical bond in the connective material are excited to thermally oscillate in such a manner that the electrons break the chemical bond and leave the connective material. In doing so, the material can chip off owing to a Coulomb explosion, which intensifies the ablation process.

It is further conceivable for the bonding in step b. to be implemented by soldering, in particular by means of a previously applied solder deposit. In this context, it is preferably conceivable for the solder deposit to be applied at the predefined locations of the electronic component and to be fused via the heat of the contacts, which is applied to the package and also extends to the contact surfaces, when the package is placed at the predefined locations. Soldering is a simple yet effective method for a permanent electrical and mechanical connection of the contacts to the electronic component at the predefined locations.

Moreover, it is conceivable for the grasping in step a. to be implemented by means of a gripper comprising at least two jaws, each jaw gripping the package on an exterior lateral surface of the outermost contacts or on lateral surfaces of a contact of the package, and the heating in step b. to be implemented by transmitting heat to at least one of the contacts via the jaws. The gripping by means of a gripper is an easily controllable method for grasping the package. The package can be gripped on the exterior lateral surfaces of the corresponding outermost package, as this is a particularly easy and quickly implementable method from a procedural viewpoint. Alternatively, the package can be gripped at one of the contacts, which allows a particularly precise placement of the package, as a displacement of or damage to already placed packages or contacts by the jaws of the gripper can be precluded. The contacts are heated by one or more of the jaws being heated and the heat being dissipated to one or more of the contacts via the jaws. This bears the advantage that the heating can take place during transport to the predefined locations and that, should a laser be used for heating, damage to the support structure before the bonding is prevented. Preferably, the gripper is designed as a two-jaw parallel gripper. It is conceivable for one or both jaws to be able to be driven in order to allow gripping a contact or a package, for example via form pairing and/or force pairing.

Further according to the invention, a tool for implementing a method as described elsewhere is proposed, the tool comprising a gripper, the gripper comprising at least two jaws. The tool is characterized in that at least one of the jaws comprises a heat-transmission area. Via the heat-transmission area, it becomes possible to heat the at least one contact while the gripper is holding the package. In doing so, a laser beam is directly directed on the heat-transmission area and the heat is conveyed via the jaw to the contact touched by the jaw. This bears the advantage that damage to the support structure is prevented before bonding.

The term “jaw” refers to the part of the gripper which comes into direct contact with the object to be gripped, i.e., the contact or the package. The jaw can be exchangeable and can be equipped with special friction pads to increase stiction. In particular, a jaw can be designed as a gripping finger which in conjunction with at least one other gripping finger serves to hold the package or the contact. At least one of the jaws is mounted so as to be moveable about an axis. The jaw preferably has a shape adapted to the function. Particularly preferably, the jaw is flat and/or tapers.

The term “heat-transmission area” refers to a surface or a part, in particular an exposed surface or an exposed part, at a jaw, either of which can be heated by means of a laser and is suitable for transmitting heat input via the laser to a contact or a package having several contacts.

Further details, features and advantages of the invention can be derived from the following description of the preferred exemplary embodiments in conjunction with the dependent claims. Here, the individual features can be realized on their own or in combination with each other. The invention is not limited to the exemplary embodiments. The exemplary embodiments are shown schematically in the figures. In the individual figures, the same reference numerals refer to the same elements, to elements equal in function and/or to elements corresponding to each other in function.

### BRIEF DESCRIPTION OF THE DRAWINGS

FIG. 1 shows an isometric view of a first package according to the invention.

FIGS. 2A and 2B show a top view and a frontal view, respectively, of a second embodiment of a package according to the invention.

FIG. 3 shows an isometric view of a third embodiment of a package according to the invention.

FIGS. 4A, 4B, and 4C show a lateral view, a frontal view and a top view, respectively, of a fourth embodiment of a package according to the invention.

FIGS. 5A, 5B, and 5C show individual steps of the method according to the invention.

FIG. 6 shows a first embodiment of a gripper according to the invention while implementing step b. of the method according to the invention.

FIG. 7 shows a second embodiment of a gripper according to the invention.

FIG. 8 shows a third embodiment of a gripper according to the invention.

FIG. 9 shows a fourth embodiment of the gripper according to the invention.

### DETAILED DESCRIPTION

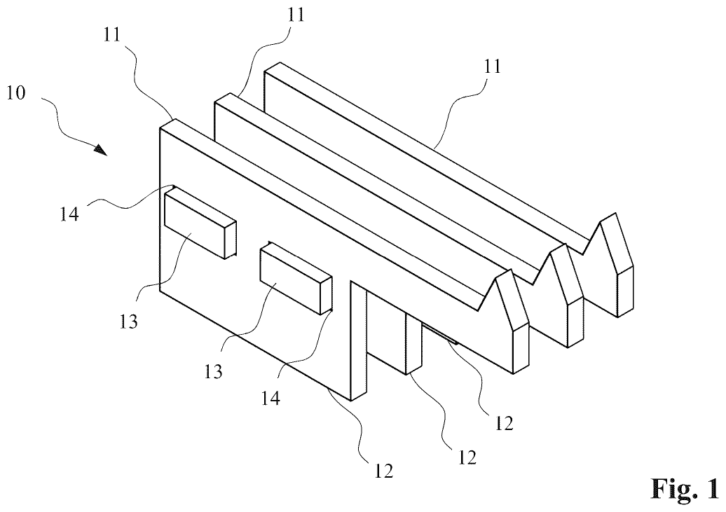

FIG. 1 shows an isometric view of a first embodiment of a package 10 according to the invention. Package 10 according to the invention comprises three flat, identical contacts 11 oriented in the same direction and disposed parallel to each other. Contacts 11 each comprise a contact surface 12, which is disposed on the bottom in FIG. 1. Contact surfaces 12 of contacts 11 are disposed in one plane and are oriented in the same direction. Contacts 11 are connected via a support structure 13 designed in two parts, the two parts each being designed as a beam. The beams of support structure 13 are each disposed in a recess 14, each contact 11 having two recesses 14. Via a substance-to-substance bond of support structure 13 in recesses 14, contacts 11 of package 10 are fixed in their distance and their orientation with respect to each other.

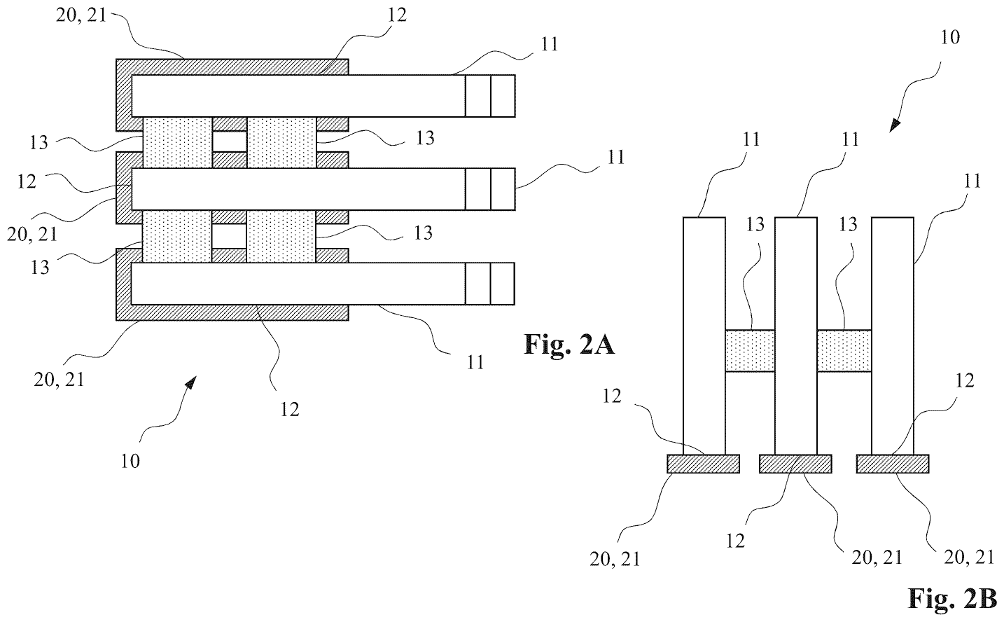

FIG. 2A shows a top view and FIG. 2B shows a frontal view of a second package 10 according to the invention. Package 10 also comprises three contacts 11, which are connected via a support structure 13 and are fixed thereby in their distance and their orientation. Contacts 11 each comprise a contact surface 12, contact surfaces 12 being disposed at a predefined location 21 of an electronic component 20 and being connected thereto in FIGS. 2A and 2B. As can be seen in particular in FIG. 2B, contact surfaces 12 are located in one plane and are oriented in the same direction. Contacts 11 are identical, are oriented in the same direction and are flat and disposed parallel to each other.

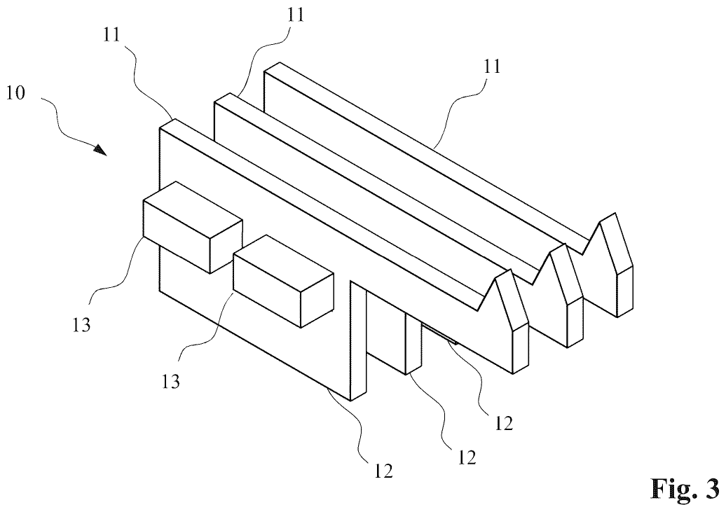

FIG. 3 shows an isometric view of a third embodiment of a package 10 according to the invention. Package 10 according to the invention comprises three flat, identical contacts oriented in the same direction and disposed parallel to each other. Contacts 11 each comprise a contact surface 12, which is disposed on the bottom in FIG. 3. Contact surfaces 12 of contacts 11 are located in one plane and are oriented in the same direction. Contacts 11 are connected via a support structure 13, which is designed in multiple parts, the parts being designed as a block. In this context, two blocks are disposed between two contacts 11 in each instance. On outermost contact 11, two blocks are also disposed on the outside, a fourth contact 10 (not shown) being able to be disposed on the two blocks. Via a substance-to-substance bond of the blocks of support structure 13, contacts 11 of package 10 are fixed in their distance and their orientation with respect to each other.

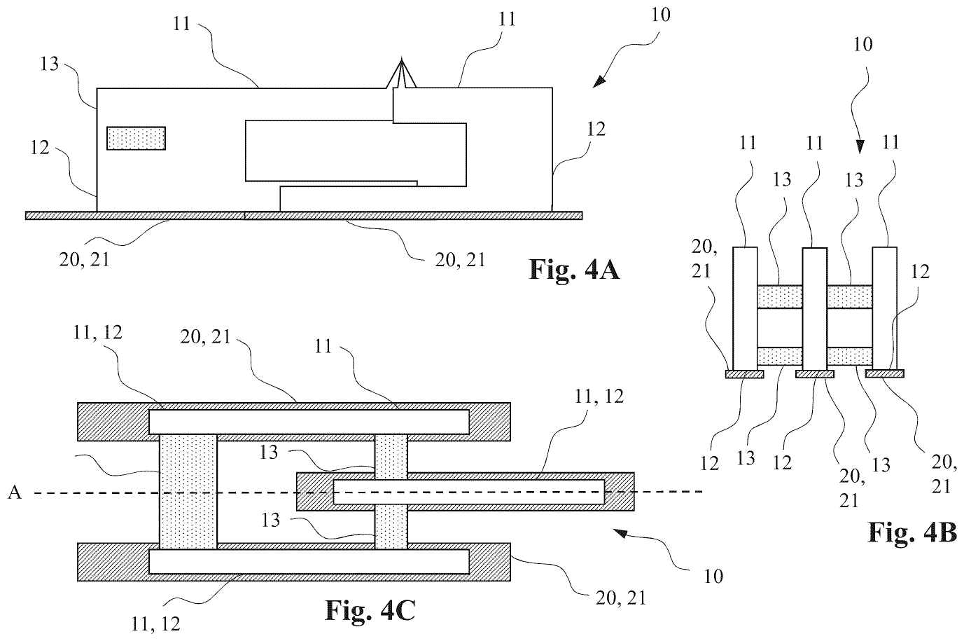

FIG. 4A shows a lateral view, FIG. 4B shows a frontal view, and FIG. 4C shows a top view of a fourth embodiment of a package 10 according to the invention. The lateral view in FIG. 4A is a cut view of package 10, which has been cut along axis A in FIG. 4C. Package 10 also comprises three contacts 11, which are fixed in their distance and their orientation via a support structure 13. Contacts 11 are flat and each comprise a contact surface 12, contact surfaces 12 being disposed in three predefined locations 21 of an electronic component 20. Contacts 11 are parallel, albeit being oriented in different directions, the two exterior contacts 11 being oriented in the same direction and center contact 11 being rotated by 180°. Support structure 13 is designed in three pieces. In this context, it can be easily seen that a part of support structure 13 designed as a block and a cuboid is disposed in the lower part of contacts 11 between contacts 11 in each instance. Block-shaped support structure 13 is disposed on a first contact 11 by a first lateral surface and is disposed on a second contact 11 by a second lateral surface. Between both exterior contacts 11 of package 10, another part of support structure 13 is disposed which is connected to one of the contacts 11 as a block by a first lateral surface and to the other contact 11 as a block by a second lateral surface being opposite the first lateral surface.

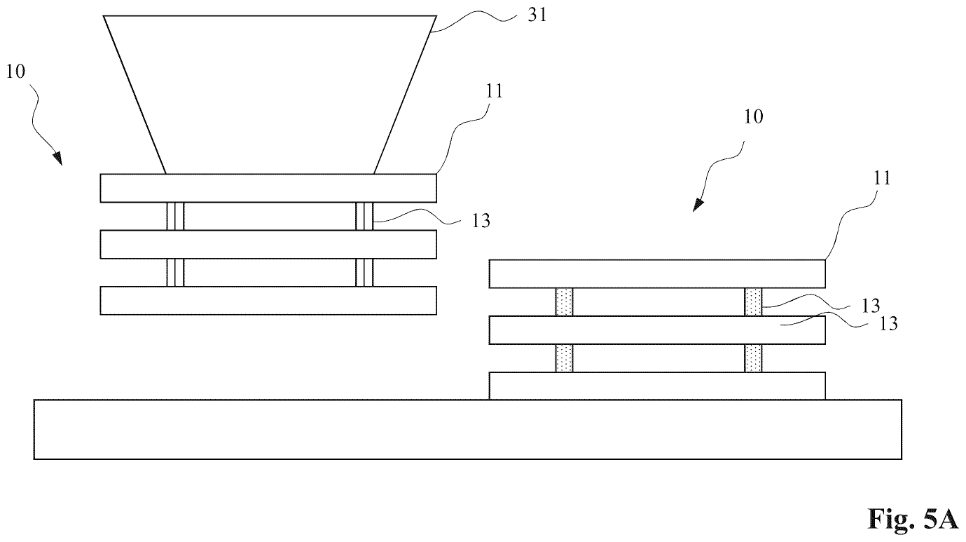

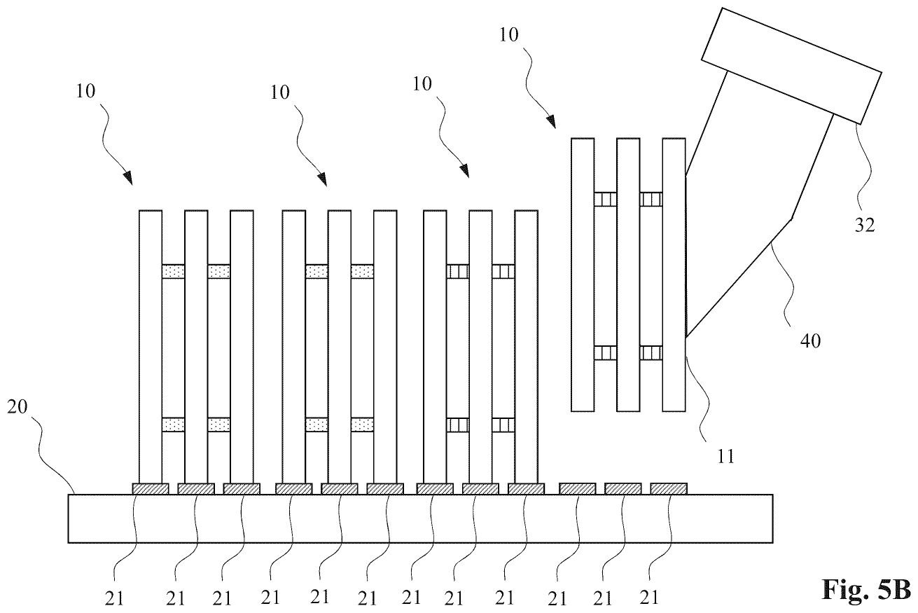

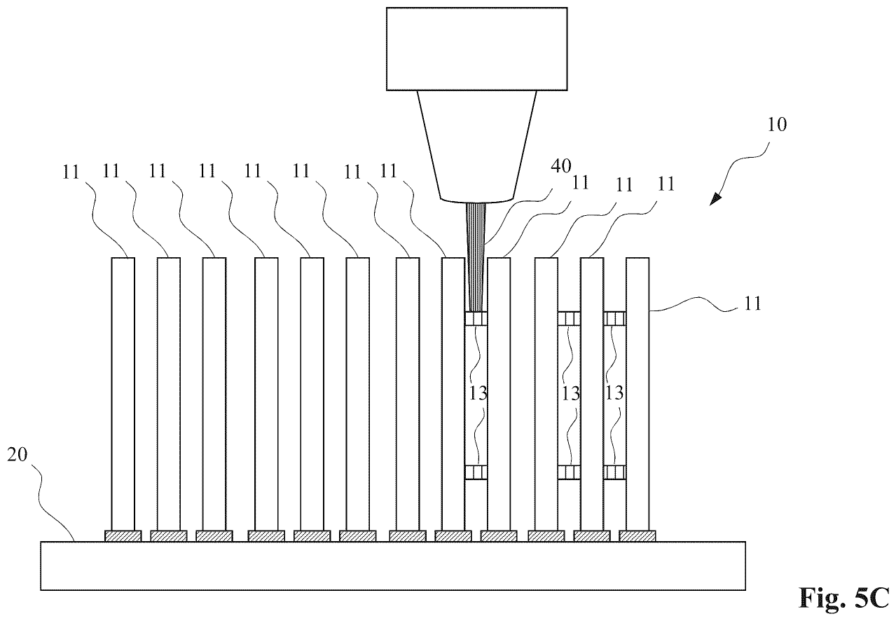

FIG. 5A shows step a. of the method according to the invention. In this context, a package 10, which comprises three contacts 11 connected to each other via a support structure 13, is grasped via a grasping tool 31. FIG. 5A further shows a second, identical package which, however, is not grasped.

FIG. 5B shows step b. of the method according to the invention, in which package 10 grasped in step a. is heated by a heating tool 32. Grasping tool 31 is not shown in this context. Heating tool 32 is a laser, which heats package 10 by means of a laser beam 40. Furthermore, an electronic component 20 is shown having a plurality of predefined locations 21. In this context, packages 10 are already disposed at predefined locations 21. It can be further seen in which predefined location 21 package 10 heated in FIG. 5B is to be disposed. Here, contacts 11 of heated packages 10 are placed at predefined locations 21 of electronic component 20, which are still free, and are soldered thereon by means of heat.

FIG. 5C shows step c. of the method according to the invention, in which support structures 13 of packages 10 are cut by means of a cutting tool 33. Owing to this, contacts 11 which do not have a direct electrical connection are separated. Electronic component 20 can subsequently be connected to other electronic components via contacts 11. Support structure 13 is cut by means of a laser beam 40 emitted from a laser.

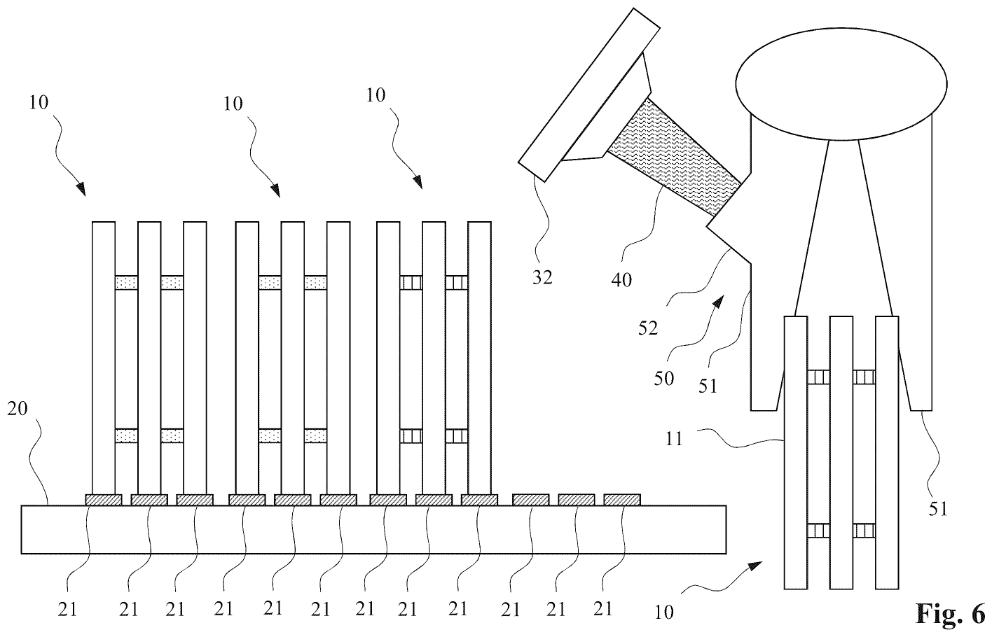

FIG. 6 shows a first embodiment of a gripper 50 while implementing step b. of the method according to the invention. Gripper 50 has gripped a package 10 using two jaws 51. In this context, one jaw 51 abuts against an exterior lateral surface of exterior contacts 11. Gripper 50 transports package 10 to still free predefined locations 21 on an electronic component 20, on which other packages 10 are already disposed. A laser beam 40 of a heating tool 32 designed as a laser is directed at a heat-transmission area 52. This heats heat-transmission area 52 and the heat is conveyed to contact 11 via jaw 51, meaning said contact 11 also heats up, heated contacts 11 thus being able to be bonded at predefined locations 21.

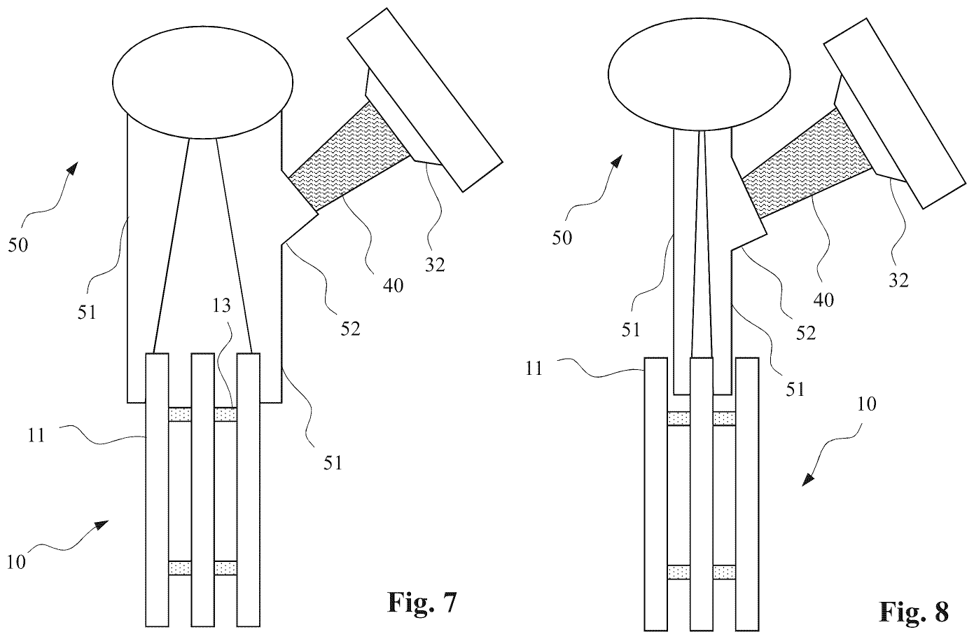

FIG. 7 shows a second embodiment of a gripper 50 according to the invention. Gripper 50 corresponds to gripper 50 shown in FIG. 6, with heat-transmission area 52 being disposed on the other jaw 51. Gripper 50 has gripped a package 10 having three contacts 11. A laser beam 40 of a heating tool 32 designed as a laser is directed at heat-transmission area 52. This heats heat-transmission area 52 and the heat is conveyed via jaw 51 to contact 11 shown on the right in FIG. 7, meaning said contact 11 also heats up. The other contacts are heated via support structure 13, which conveys the heat from contact 11 shown on the right in FIG. 7 to the other contacts.

FIG. 8 shows a third embodiment of a gripper 50 according to the invention. It corresponds to gripper 50 shown in FIG. 7, with jaws 51 being narrower. This allows inserting jaws 51 of gripper 50 at least partially in the gap between two contacts 11. Thus, gripper 50 can grip package 10 at center contact 11. A laser beam 40 of a heating tool 32 designed as a laser is directed at heat-transmission area 52. This heats heat-transmission area 52 and the heat is conveyed to center contact 11 via jaw 51.

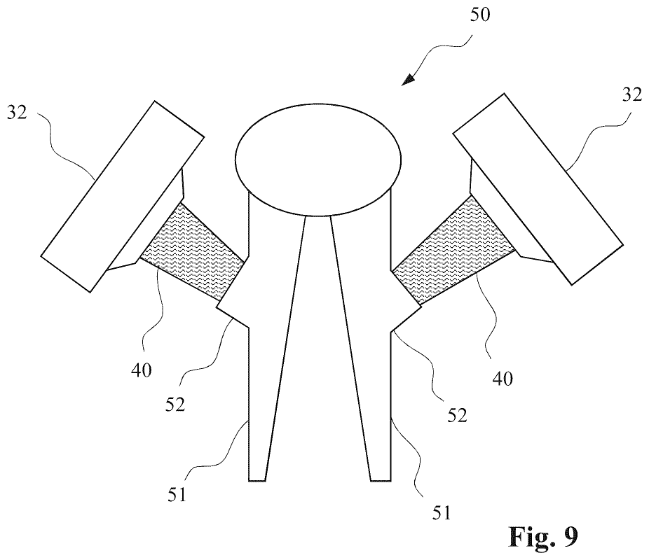

FIG. 9 shows a third embodiment of a gripper 50. It corresponds to gripper 50 shown in FIG. 7, with both jaws 51 comprising a heat-transmission area 52, at which a laser beam 40 of a heating tool is directed.

### LIST OF REFERENCE NUMERALS

10 package
11 contact
12 contact surface
13 support structure
14 recess
20 electronic component
21 predefined location
31 grasping tool
32 heating tool
33 cutting tool
40 laser beam
50 gripper
51 jaws
52 heat-transmission area

What is claimed is:

1. A package comprising at least two contacts for microtechnology, the contacts each having a contact surface, the contacts being connected to at least one support structure and the contacts being spaced apart from each other and disposed in such a manner that the contact surfaces are disposed in one plane and are oriented in the same direction, wherein the support structure is made of a connective material being separable and/or destroyable by a laser.

2. The package according to claim 1, wherein the contacts are made of a contact material, the connective material having a lower combustion and/or melting point than the contact material.

3. The package according to claim 1, wherein the contacts are flat and disposed parallel to one another.

4. The package according to claim 1, wherein the contacts are designed to be identical and/or different.

5. The package according to claim 4, wherein the contacts are oriented in the same direction and/or in different directions.

6. The package according to claim 1, wherein at least one contact comprises at least one recess.

7. The package according to claim 1, wherein the support structure comprises at least one bar.

8. The package according to claim 7, wherein the bar is disposed laterally on the contacts.

9. The package according to claim 1, wherein the support structure comprises at least one block, the block being disposed between the contacts.

10. The package according to claim 1, wherein the package comprises at least three contacts and the support structure is designed in multiple pieces, a part of the support structure being connected to two contacts.

11. The package according to claim 1, wherein the support structure is connected to the contacts in a substance-to-substance bond and/or is designed monolithical with the contacts.

12. The package according to claim 1, wherein the package is constructed in layers, in particular by ion plating.

13. The package according to claim 1, wherein the package has a length, a width and/or a height of maximally 2500 μm.

14. A method for handling the package according to claim 1, the method comprising the following steps:
a. grasping the package,
b. heating at least one contact of the contacts and bonding the contact surfaces of all contacts of the package, and
c. separating and/or destroying the support structure by a laser.

15. The method according to claim 14, wherein the separation and/or destruction in step c is implemented by ablation by the laser.

16. The method according to claim 14, wherein the bonding in step b is implemented by soldering, in particular by a previously applied solder deposit.

17. The method according to claim 14, wherein the grasping in step a is implemented by a gripper comprising at least two jaws, each jaw gripping the package on an exterior lateral surface of the outermost contacts or on lateral surfaces of a contact of the package, and wherein the heating in step b is implemented by transmitting heat to at least one of the contacts via the jaws.

18. A tool for implementing the method according to claim 14, the tool comprising a gripper comprising at least two jaws, wherein at least one of the jaws comprises a heat-transmission area.
